(19) United States
(12) Patent Application Publication
(10) Pub. No.: US 2026/0215329 A1
(43) Pub. Date: Jul. 23, 2026

(54) SURFACE-CURED ACID ANHYDRIDE EPOXIES

(71) Applicant: TEXAS INSTRUMENTS INCORPORATED, Dallas, TX (US)

(72) Inventors: Ying-Chang CHEN, Hsinchu Hsien (TW); Jane Qian LIU, Plano, TX (US)

(21) Appl. No.: 19/223,495

(22) Filed: May 30, 2025

Related U.S. Application Data
(60) Provisional application No. 63/747,552, filed on Jan. 21, 2025.

(51) Int. Cl. H10W 74/47; B81B 7/02; H10W 74/01; H10W 90/00

(52) U.S. Cl. CPC H10W 74/47; B81B 7/02; H10W 74/01; B81B 2201/042; H10W 90/754

(57) ABSTRACT

In examples, an electronic device includes a semiconductor die; a bond pad coupled to the semiconductor die; a bond wire coupled to the bond pad; and an acid anhydride material covering the bond wire and having a physicochemical property that varies by less than 1% throughout a volume of the acid anhydride material relative to a reference measurement of the physicochemical property in the acid anhydride material.

### CROSS-REFERENCE TO RELATED APPLICATIONS

The present application claims priority to U.S. Provisional Patent Application No. 63/747,552, which was filed January 21, 2025, is titled “EXPOXY SURFACE CURE PROCESS TO PREVENT MOISTURE ABSORPTION,” and is hereby incorporated herein by reference in its entirety.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique, such as by wire bonding.

### SUMMARY

In examples, an electronic device includes a semiconductor die; a bond pad coupled to the semiconductor die; a bond wire coupled to the bond pad; and an acid anhydride material covering the bond wire and having a physicochemical property that varies by less than 1% throughout a volume of the acid anhydride material relative to a reference measurement of the physicochemical property in the acid anhydride material.

In examples, a method for manufacturing an electronic device includes dispensing an acid anhydride material on a bond wire, the bond wire coupled to a semiconductor die via a bond pad; applying heat to the acid anhydride material by a halogen heating lamp; and curing the acid anhydride material after the application of the heat.

### BRIEF DESCRIPTION OF THE DRAWINGS

FIG. 1 is a flow diagram of a method for manufacturing a semiconductor package including surface-cured acid anhydride epoxies, in accordance with various examples.

FIGS. 2A, 2B, and 2C depict dispensing equipment useful to manufacture a semiconductor package including surface-cured acid anhydride epoxies, in accordance with various examples.

FIGS. 3A, 3B, 3C, 3D, and 3E are a process flow depicting the manufacture of a semiconductor package including surface-cured acid anhydride epoxies, in accordance with various examples.

FIGS. 4A and 4B are a process flow depicting the manufacture of a semiconductor package including surface-cured acid anhydride epoxies, in accordance with various examples.

FIGS. 5A, 5B, 5C, and 5D are perspective, perspective, top-down, and profile views, respectively, of a semiconductor package including surface-cured acid anhydride epoxies, in accordance with various examples.

FIGS. 6A, 6B, and 6C are cross-sectional, perspective, and top-down views, respectively, of a semiconductor package including surface-cured acid anhydride epoxies, in accordance with various examples.

FIGS. 7A, 7B, and 7C, are cross-sectional, perspective, and bottom-up views, respectively, of a semiconductor package including surface-cured acid anhydride epoxies, in accordance with various examples.

FIG. 8 is a cross-sectional view of a surface-cured acid anhydride epoxy, in accordance with various examples.

FIG. 9 is a block diagram of an electronic system including a semiconductor package having a surface-cured acid anhydride epoxy, in accordance with various examples.

### DETAILED DESCRIPTION

Acid anhydride–based epoxy materials such as glob tops and mold compounds are widely used in semiconductor packaging to protect delicate structures, including bond wires and metal interconnects. These materials provide mechanical support, seal out moisture and contaminants, and help the device withstand temperature changes during operation. Epoxy mold compounds are typically used to cover and protect a range of structures in the semiconductor package, while glob tops are used in more localized areas, such as over bond wires. To form a solid and durable structure, these materials are cured by heat, which triggers a chemical reaction that hardens the material and bonds the material to surrounding surfaces. When properly cured, acid anhydride–based materials create a strong, stable coating that holds structures in place and prevents cracking, corrosion, or other damage during the life of the semiconductor package.

However, if these acid anhydride materials are not cured soon after application, the materials can absorb moisture from the surrounding air. This is because uncured acid anhydride compounds contain chemical groups that attract water, which can interfere with the curing process and weaken the final structure. Moisture absorption before curing can lead to multiple technical challenges: the acid anhydride material may have shifting properties (e.g., coefficient of thermal expansion (CTE), glass transition temperature (Tg), elastic modulus, dimensional stability, and flexural strength); may not bond properly to structures within the semiconductor package, leading to delamination; bond wires may come loose or break; mechanical stress may accumulate in optical parts like glass, causing cracks; and the surface appearance of the acid anhydride material can change—often becoming shinier—which may cause quality concerns during inspection. In attempts to solve these challenges, manufacturers have used various approaches (e.g., hot plates) to cure the acid anhydride material after application. However, hot plates are slow, may not heat the entire part evenly, and are not easy to scale for high-volume production. In all such approaches, the curing step represents a production line bottleneck because it reduces throughput relative to the throughput that would be realized if the curing step were omitted. An efficient technique for mitigating acid anhydride moisture absorption remains elusive.

This description presents various examples of an acid anhydride surface-curing technique that mitigates the technical challenges described above. Specifically, an in-situ surface-curing technique is useful to cure acid anhydride materials after the acid anhydride materials are dispensed. Halogen lamps (or other convection-based heat sources) provide directed heating, which facilitates instant and efficient in-situ curing of acid anhydride materials, thereby preventing moisture absorption into the acid anhydride materials. Furthermore, the halogen heating technique is highly efficient because halogen lamps may cure the acid anhydride materials during a production line stage in which manufacturing operations usually are not performed. Thus, the halogen heating step does not represent a bottleneck.

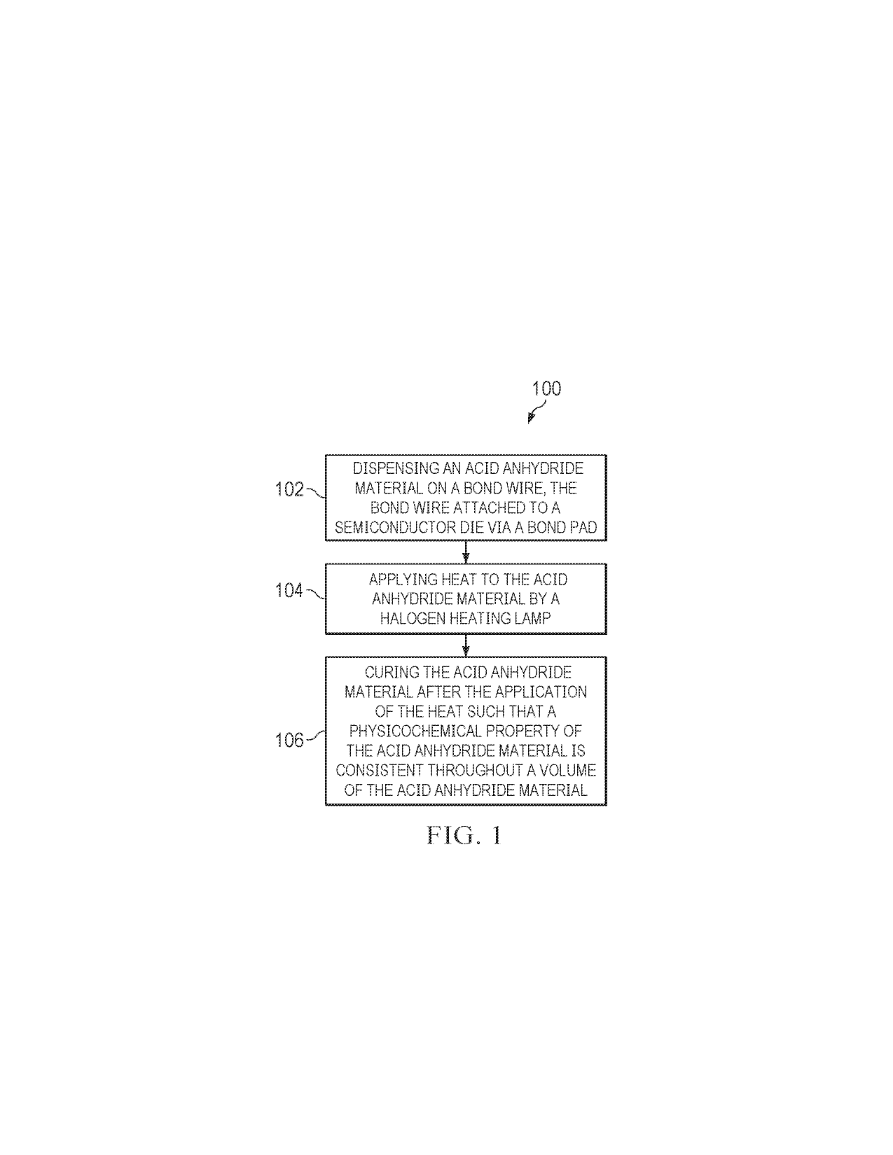

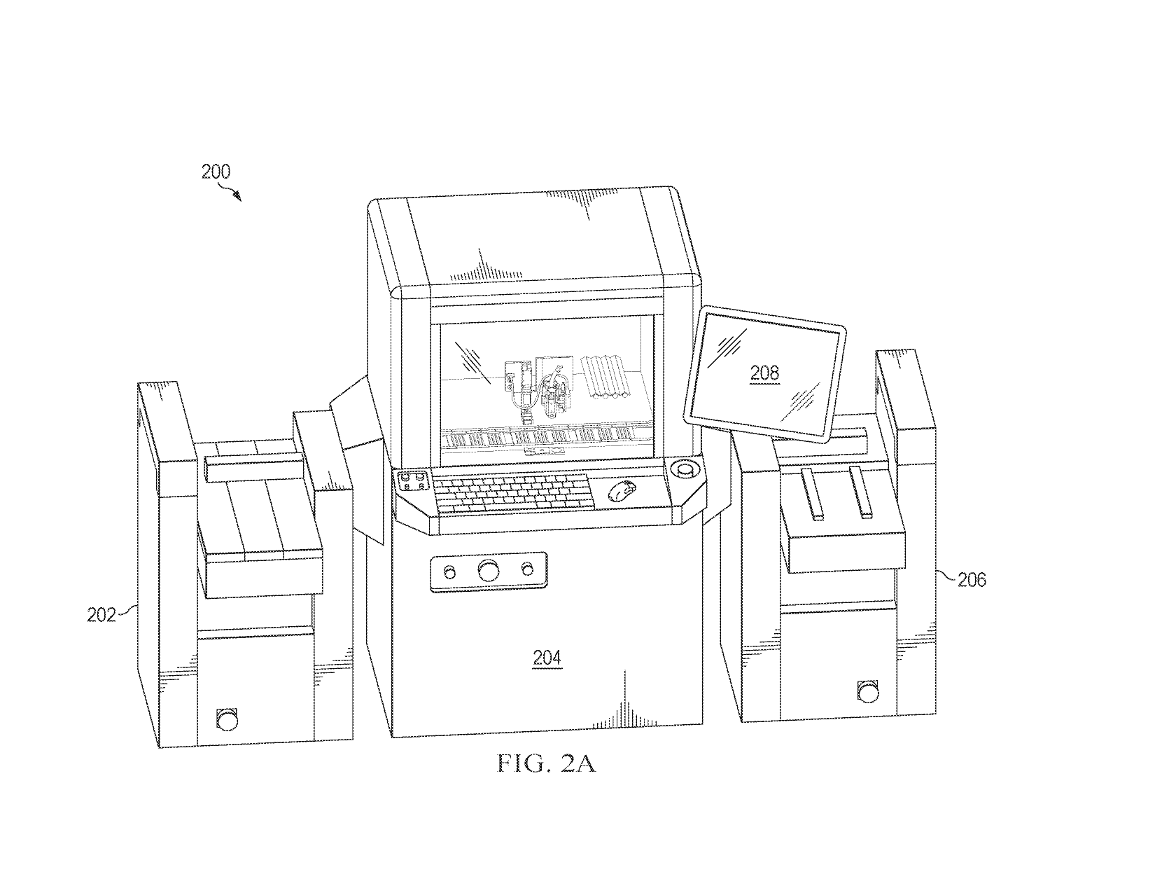

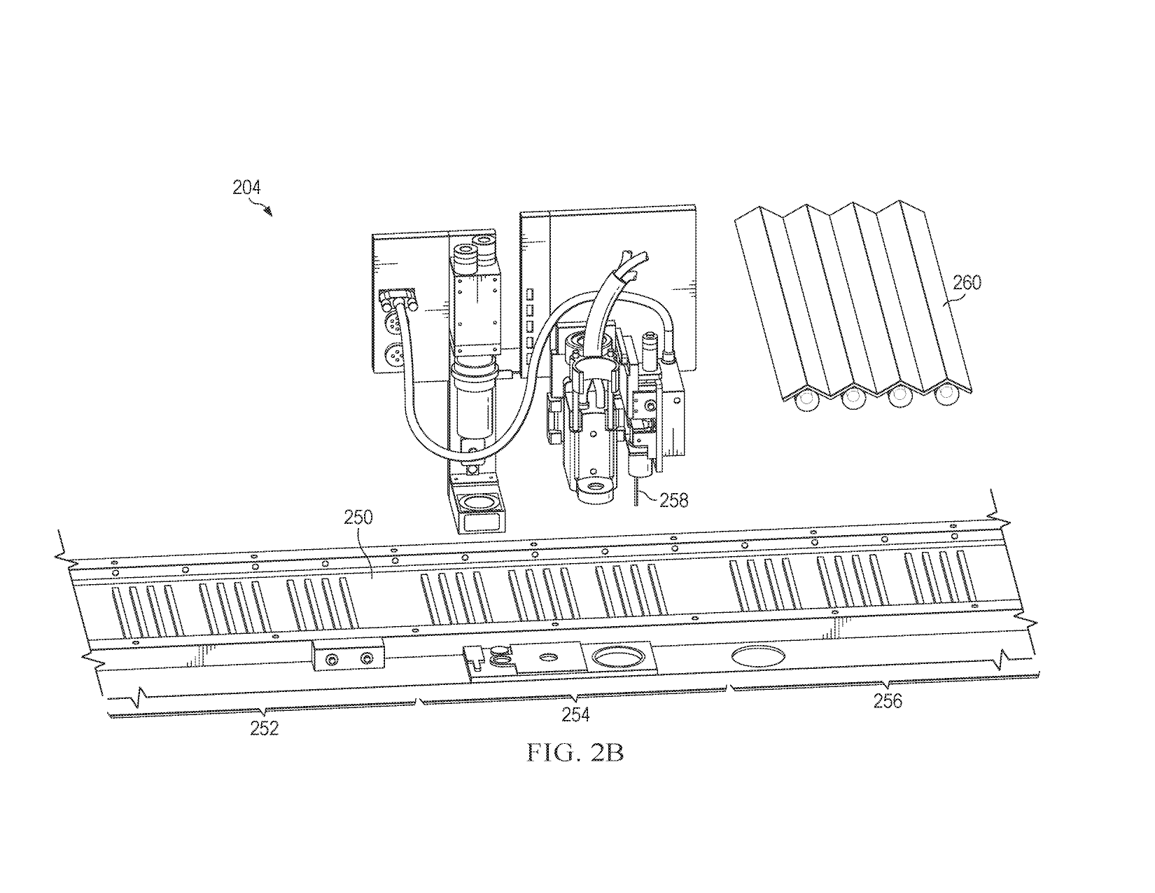

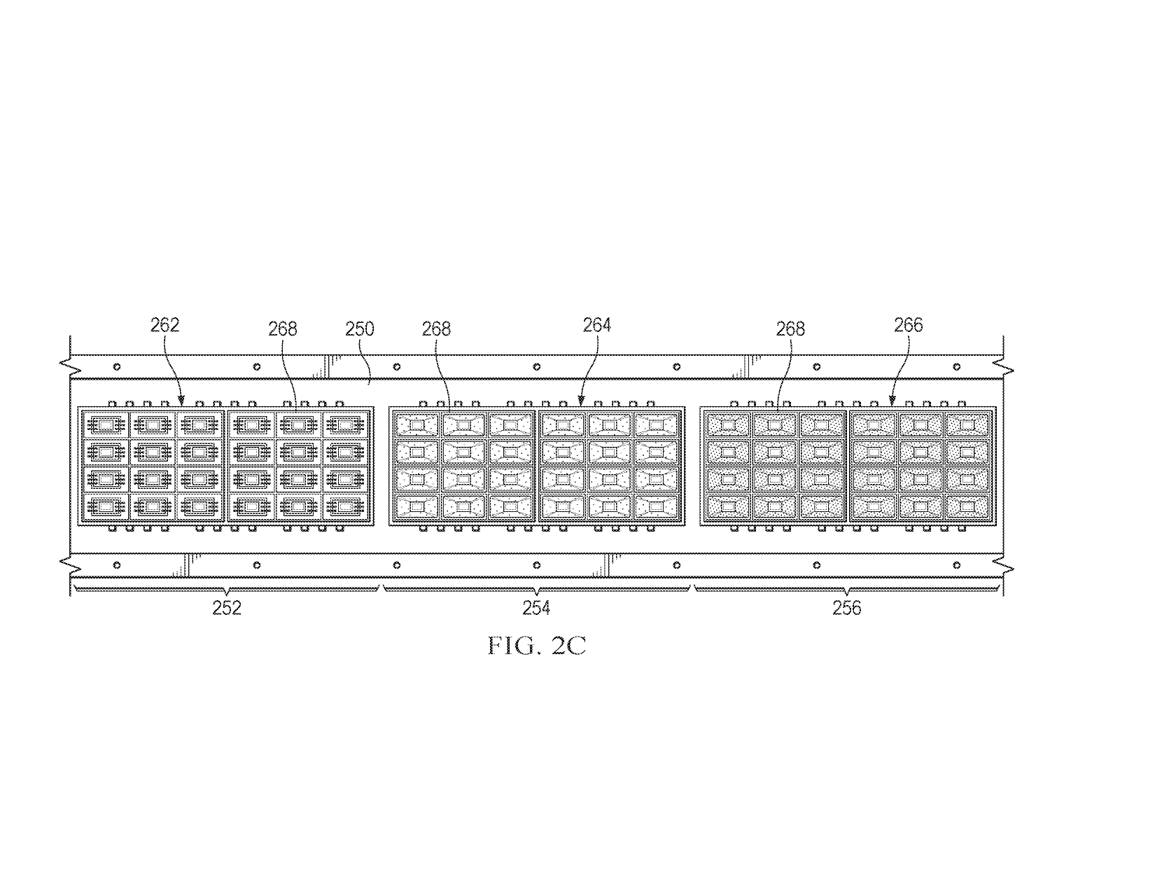

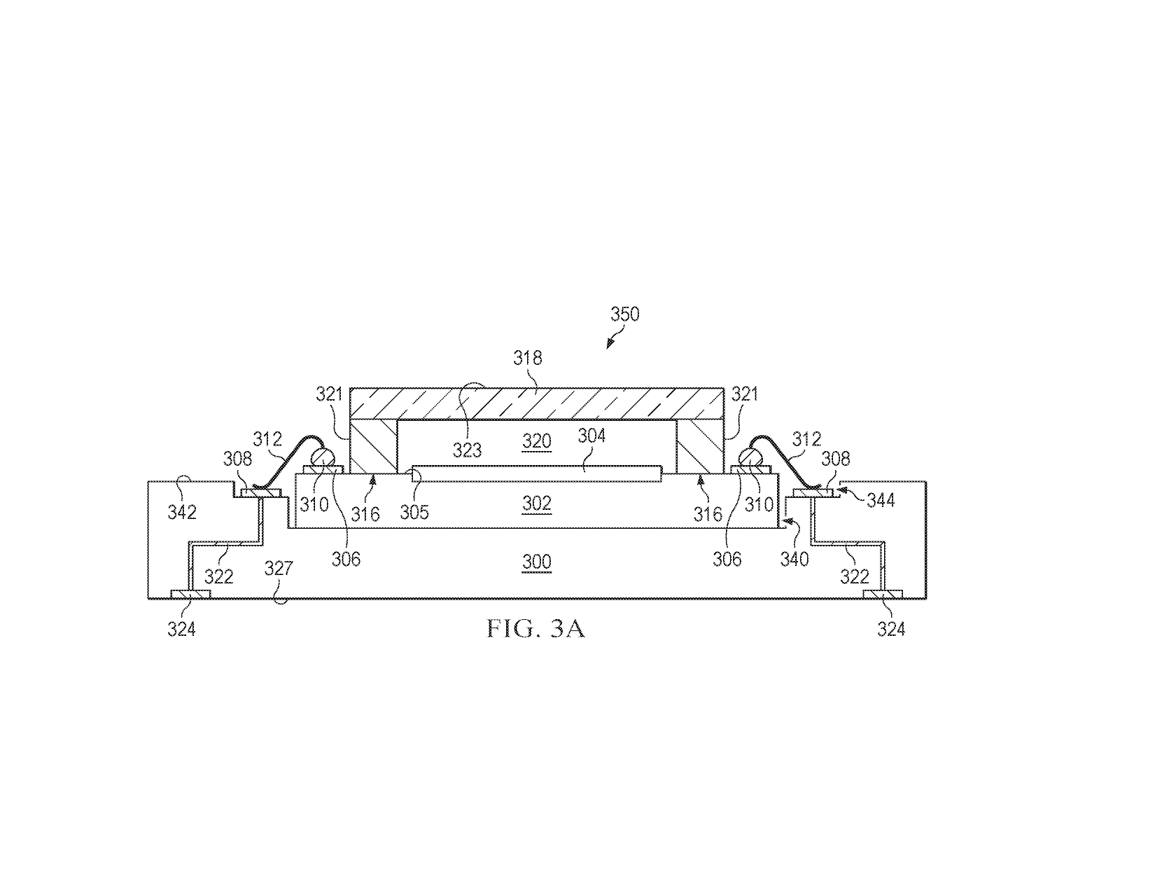

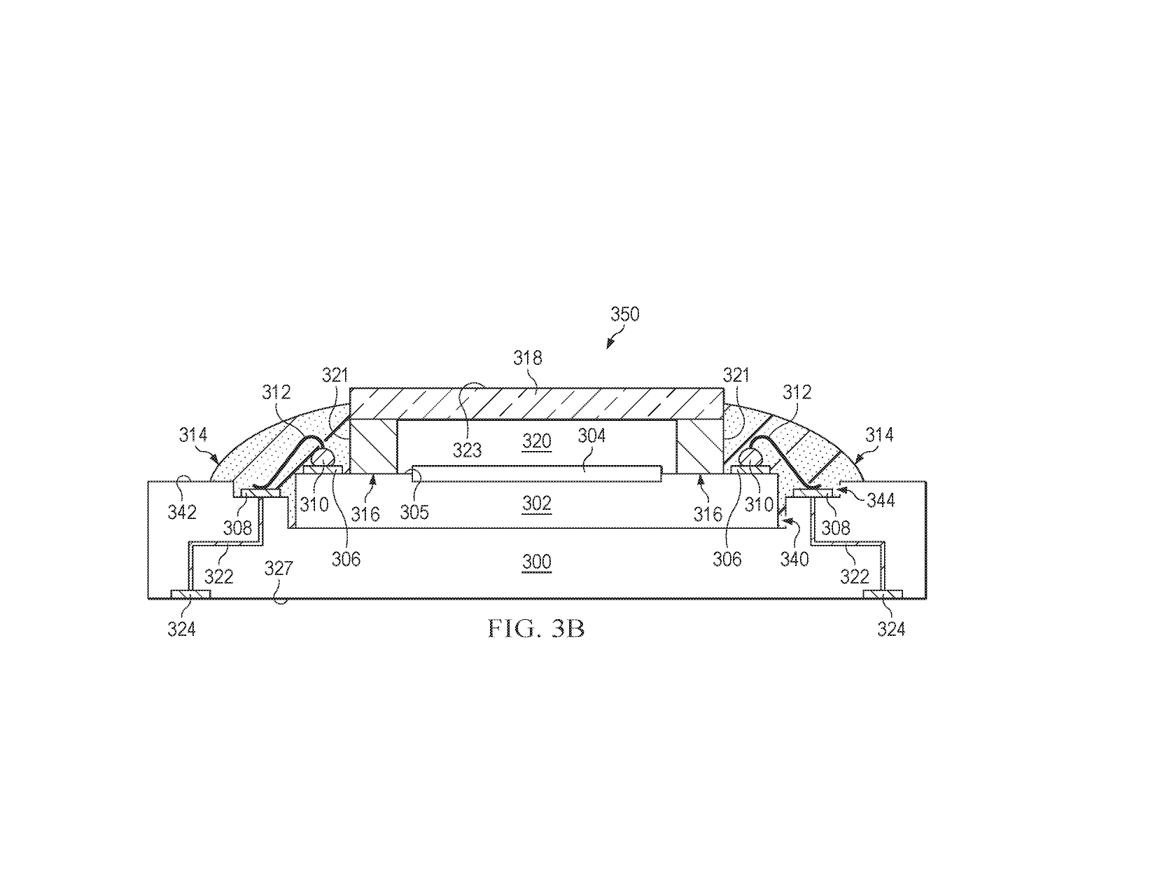

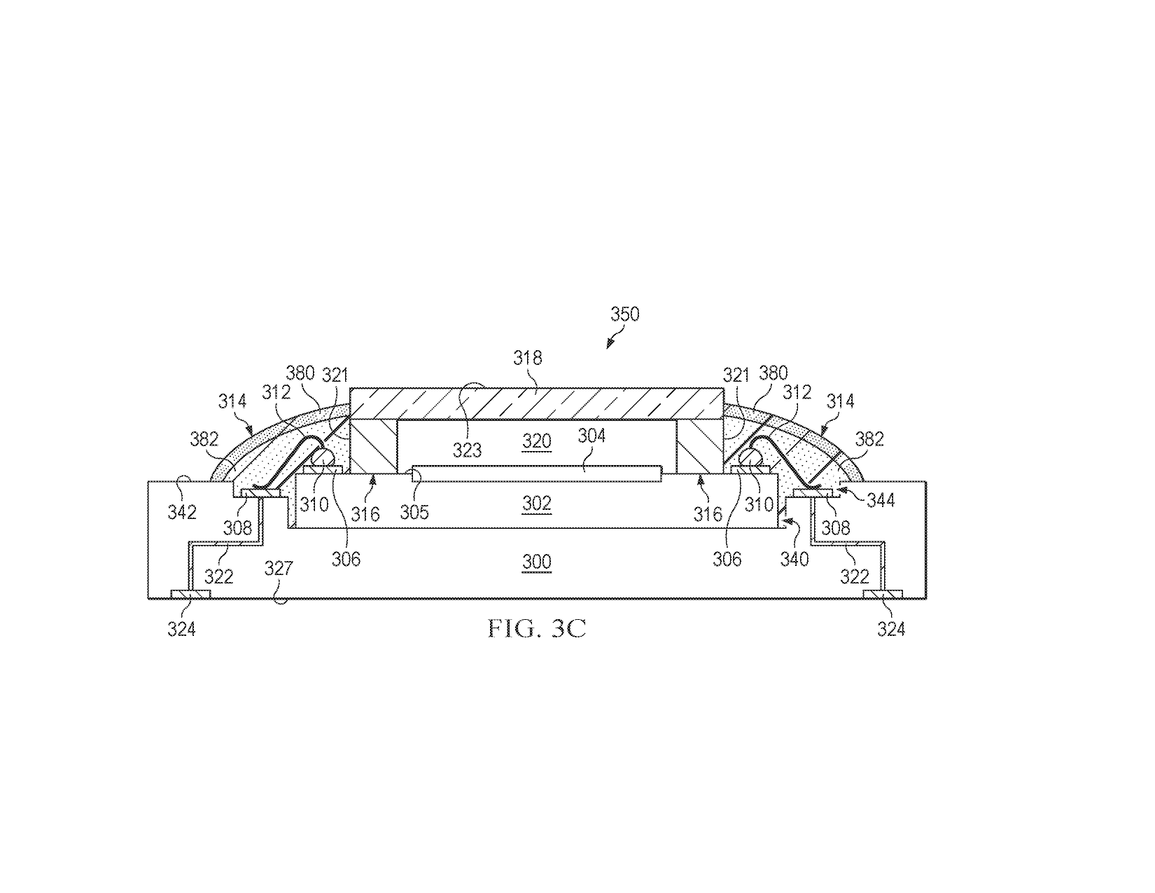

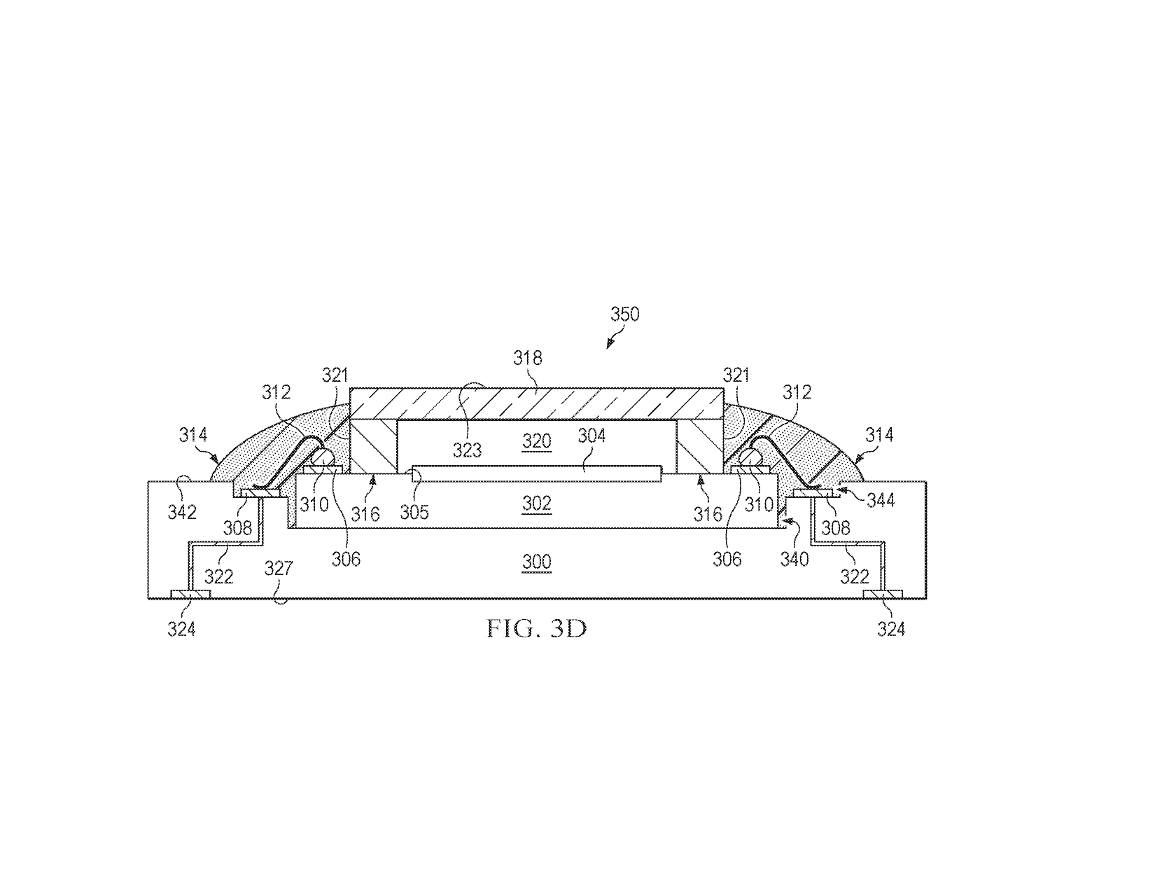

FIG. 1 is a flow diagram of a method 100 for manufacturing a semiconductor package including halogen-cured acid anhydride materials, in accordance with various examples. FIGS. 2A-2C depict equipment useful to manufacture a semiconductor package including halogen-cured acid anhydride materials, in accordance with various examples. FIGS. 3A-3E are a process flow depicting the manufacture of a semiconductor package including halogen-cured acid anhydride materials, in accordance with various examples. Accordingly, FIGS. 1-3E are now described in parallel with each other.

The example method 100 may include dispensing an acid anhydride material on a bond wire (102). The bond wire is coupled to a semiconductor die via a bond pad (102). The method 100 may include applying heat to the acid anhydride material by a halogen heating lamp (104). The method 100 may include curing the acid anhydride material after the application of the heat such that a physicochemical property of the acid anhydride material is consistent throughout a volume of the acid anhydride material (106).

The method 100 may be performed by acid anhydride dispensing equipment 200. As FIG. 2A shows, the acid anhydride dispensing equipment 200 may include a loader 202, a dispense station 204, and an unloader 206. A display 208 is useful to operate the acid anhydride dispensing equipment 200. Workpieces may be provided to the loader 202, such as by a technician. (A workpiece is a tray or fixture that holds arrays of semiconductor packages in defined positions to enable precise deposition of acid anhydride material onto designated areas of each package during the encapsulation process.) The loader 202 provides the workpieces to a conveyor belt 250, which is depicted in FIG. 2B along with other features of the interior of the dispense station 204. The conveyor belt 250 may be inside the dispense station 204 and may convey workpieces through the dispense station 204 to the unloader 206. More specifically, the conveyor belt 250 may convey workpieces through a staging area 252, a dispensing area 254 (where step 102 of FIG. 1 is performed), and a halogen heating area 256 (where step 104 of FIG. 1 is performed), all of which are within the dispensing station 204. Workpieces in the staging area 252 are next in line to receive acid anhydride material in the dispensing area 254. The conveyor belt 250 may advance a workpiece from the staging area 252 to the dispensing area 254, where a dispensing unit 258 dispenses acid anhydride material (e.g., epoxy material such as glob top, mold compound, or another thermosetting polymer containing epoxide resins and acid anhydride hardeners) onto the workpiece (e.g., onto bond wires of semiconductor packages arranged on the workpiece). The dispensing unit 258 may include a needle to facilitate precise deposition of the acid anhydride material. In this way, the dispensing unit 258 performs step 102 of the method 100.

The conveyor belt 250 may subsequently advance the workpiece from the dispensing area 254 to the halogen heating area 256 to perform step 104 of FIG. 1. A halogen heating lamp 260 may be suspended over the conveyor belt 250 in the halogen heating area 256. The heat provided by the halogen heating lamp 260, the distance between the halogen heating lamp 260 and the workpiece on the conveyor belt 250, and other such parameters are set as appropriate to achieve rapid, in-situ surface curing of the acid anhydride material dispensed by the dispensing unit 258. The temperature provided by the halogen heating lamp 260 ranges from 100 degrees Celsius to 150 degrees Celsius, with a temperature below this range being disadvantageous because the surface cure will be inadequate to prevent acid anhydride material interaction with moisture, and with a temperature above this range being disadvantageous because such high temperatures will cause intrinsic properties of the acid anhydride material to change. The halogen heating lamp 260 heats the acid anhydride materials on the workpiece to this temperature range for a duration ranging from 1 minutes to 10 minutes, with a duration shorter than this range being disadvantageous because the surface cure will be inadequate to prevent acid anhydride material interaction with moisture, and with a duration longer than this range being disadvantageous because manufacturing efficiency is negatively impacted. The distance between the halogen heating lamp 260 and the workpiece on the conveyor belt 250 ranges from 10 centimeters to 50 centimeters, with a distance below this range being disadvantageous because the surface cure will be nonuniform across the acid anhydride materials on the workpiece, and with a distance above this range being disadvantageous because of decreased curing efficiency. The halogen heating lamp 260 cures the acid anhydride material rapidly, and more specifically, the halogen heating lamp 260 cures an outer portion of the acid anhydride material rapidly such that no moisture penetrates this outer portion of the acid anhydride material. After the outer portion of the acid anhydride material has been cured, an inner portion of the acid anhydride material may be cured or may remain uncured. This inner portion of the acid anhydride material may be cured by keeping the workpiece in the halogen heating area 256 for an extended period of time, by placing the workpiece in an oven or other heating device after the workpiece has been output by the unloader 206, etc. In some examples, no additional heat is applied, and the inner, uncured portion of the acid anhydride material cures over an extended time at room temperature. This variety in cure times for the inner portion of the acid anhydride material is permissible because the outer portion of the acid anhydride material has already been cured by the halogen heating lamp 260, thus forming an outer “shell” that prevents moisture penetration into the acid anhydride material. In this way, the halogen heating lamp 260 performs step 104 of the method 100. Step 106 may be performed by another heat source outside of the dispense station 204, such as the halogen heating oven described below.

FIG. 2C shows three example workpieces on the conveyor belt 250 (e.g., FIG. 2B) in the dispense station 204 (e.g., FIGS. 2A and 2B). More specifically, a workpiece 262 is in the staging area 252 of the dispense station 204, a workpiece 264 is in the dispensing area 254 of the dispense station 204, and a workpiece 266 is in the halogen heating area 256 of the dispense station 204. Each of the workpieces 262, 264, and 266 includes multiple semiconductor packages 268 arranged in arrays. The semiconductor packages 268 in the staging area 252 include exposed bond wires, meaning that the bond wires of the semiconductor packages 268 are not covered by an acid anhydride material. The semiconductor packages 268 in the dispensing area 254 are covered by an acid anhydride material that has been deposited by the dispensing unit 258. The acid anhydride material on the semiconductor packages 268 in the halogen heating area 256 are at least partially cured, meaning that the outer portions of these acid anhydride materials have been cured to prevent moisture penetration into the acid anhydride material. Because moisture penetration is mitigated, the deleterious effects of moisture penetration as described above are also mitigated. The halogen heating lamp 260 cures the outer portion of the acid anhydride material within 3 minutes of the acid anhydride material being dispensed, with a cure time above this threshold strongly predisposing the acid anhydride material to moisture penetration. The halogen heating lamp 260 cures the acid anhydride material to a depth of at least 500 microns, with a cure depth below this threshold being disadvantageous because the bulk acid anhydride epoxy properties will degrade due to the reaction with moisture penetration through the acid anhydride surface.

FIG. 3A is a cross-sectional view of an example semiconductor package 350 in the staging area 252, for example, if the semiconductor package 350 was positioned on the workpiece 262. The example semiconductor package 350 includes a substrate 300, which in some examples may be a ceramic substrate. The semiconductor package 350 includes a semiconductor die 302 on the substrate 300. The semiconductor die 302 may include one or more devices 304 on a device side 305 of the semiconductor die 302. The one or more devices 304 may include circuitry (e.g., complementary metal oxide semiconductor (CMOS) circuitry), one or more mirrors (such as in a micromirror array), microelectromechanical systems (MEMS) devices, etc., that may be susceptible to damage by moisture, salt, debris, and other external contaminants. The semiconductor package 350 includes bond pads 306 on the semiconductor die 302 and bond leads 308 on the substrate 300. Bond wires 312 are coupled to the bond pads 306 by ball bonds 310 and are coupled to the bond leads 308 by, e.g., stitch bonds.

A multi-sided (e.g., four-sided) structure 316 extends approximately orthogonally from the device side 305 in the vertical direction and circumscribes the one or more devices 304. A cap 318 (e.g., a transparent member, such as a glass panel) is coupled to the structure 316. The cap 318 is approximately parallel to the semiconductor die 302. The structure 316 may include, for instance, a metal stack, an interposer (e.g., a semiconductor interposer), and miscellaneous layers (e.g., oxide layers, anti-reflective coatings) that, together with the cap 318, form a seal (e.g., a hermetic seal) enclosing a cavity 320. Although not expressly depicted, the structure 316 may include a bondline. An outer surface 321 of the structure 316 faces away from the cavity 320. The cap 318 has a top surface 323.

The substrate 300 includes a metal trace 322 that is coupled to the bond lead 308 and to a metal contact 324 on an exterior and/or bottom surface 327 of the substrate 300. The metal trace 322, the bond lead 308, the bond wire 312, the ball bond 310, and the bond pad 306 establish an electrical pathway between the metal contact 324 and the semiconductor die 302.

In examples, the semiconductor package 350 includes a cavity 340 in which the semiconductor die 302 is positioned. However, in other examples, the cavity 340 may be omitted, and the semiconductor die 302 may be placed on a flat surface that is horizontally coplanar with other surfaces within the semiconductor package 350, such as a surface 342 or a shelf 344. In examples, the bond leads 308 are positioned on the shelf 344, which circumscribes the semiconductor die 302. However, in examples, the shelf 344 may be omitted, and the bond leads 308 may be positioned elsewhere, such as on the surface 342.

FIG. 3B is a cross-sectional view of the example semiconductor package 350 in the dispensing area 254, for example, if the semiconductor package 350 was positioned on the workpiece 264. An acid anhydride material 314 covers various components of the semiconductor package 350, such as the bond pads 306, bond leads 308, the ball bonds 310, the bond wires 312, and portions of the substrate 300. The acid anhydride material 314 contacts and partially covers, but may not encapsulate, the substrate 300. In some examples, the acid anhydride material 314 encapsulates the substrate 300, and in some examples, the acid anhydride material 314 covers all areas of the top surface of the substrate 300 that are not otherwise covered by other components.

The acid anhydride material 314 also contacts and covers the multi-sided structure 316. The acid anhydride material 314 contacts and partially covers the cap 318. The acid anhydride material 314 contacts and covers the outer surface 321. The acid anhydride material 314 contacts and covers part of the cap 318, but in examples, the acid anhydride material 314 does not contact or cover any portion of the top surface 323 of the cap 318. The acid anhydride material 314 seals the various components that the acid anhydride material 314 contacts and covers and is fluid-resistant, protecting such components from moisture, debris, and other damaging environmental influences.

The acid anhydride material 314 may be any epoxy containing acid anhydride, such as a glob top, a mold compound, or any other suitable acid anhydride material that serves the purposes and performs the functions attributed herein to the acid anhydride material 314. Example acid anhydrides may include hexahydrophthalic anhydride (HHPA), methylhexahydrophthalic anhydride (MHHPA), methyltetrahydrophthalic anhydride (MTHPA), tetrahydrophthalic anhydride (THPA), nadic methyl anhydride (NMA), cyclohexene-1,2-dicarboxylic anhydride (CHDA), pyromellitic dianhydride (PMDA), maleic anhydride (MA), trimellitic anhydride (TMA), and succinic anhydride (SA). The acid anhydride material 314 has a thickness adequate to cover all metals, alloys, and oxides in the structure 316, as well as the bond wires 312. Covering the structure 316 includes covering most or all of the outer surface 321 (e.g., including any orifices, interfaces between layers, and metal surfaces), as well as the interface between the structure 316 and the cap 318.

FIG. 3C is a cross-sectional view of the example semiconductor package 350 in the halogen heating area 256, for example, if the semiconductor package 350 was positioned on the workpiece 266. The structure shown in FIG. 3C is identical to that shown in FIG. 3B, except that the acid anhydride material 314 has been rapidly cured at high temperature and for a short duration of time, as described above. This type of rapid curing results in an outer portion 380 of the acid anhydride material 314 that has been cured by the halogen heating lamp 260, and an inner portion 382 of the acid anhydride material 314 that has not yet been cured.

FIG. 3D is a cross-sectional view of the example semiconductor package 350 after exiting the dispense station 204, for example, after additional curing is performed in a halogen heating oven 390 (FIG. 3E). The structure of FIG. 3D is identical to that of FIG. 3C, except that the inner portion 382 of the acid anhydride material 314 has also been cured, such as by the halogen heating oven 390. Other techniques also may be useful to cure the inner portion 382, with exposure to room temperature taking a longer duration time to cure and exposure to a heat source taking a shorter duration of time to cure. As explained, however, after the halogen heating lamp 260 has rapidly cured the outer portion 380 of the acid anhydride material 314, the acid anhydride material 314 is protected from moisture, and the inner portion 382 of the acid anhydride material 314 may be cured at any time, or allowed to self-cure at room temperature.

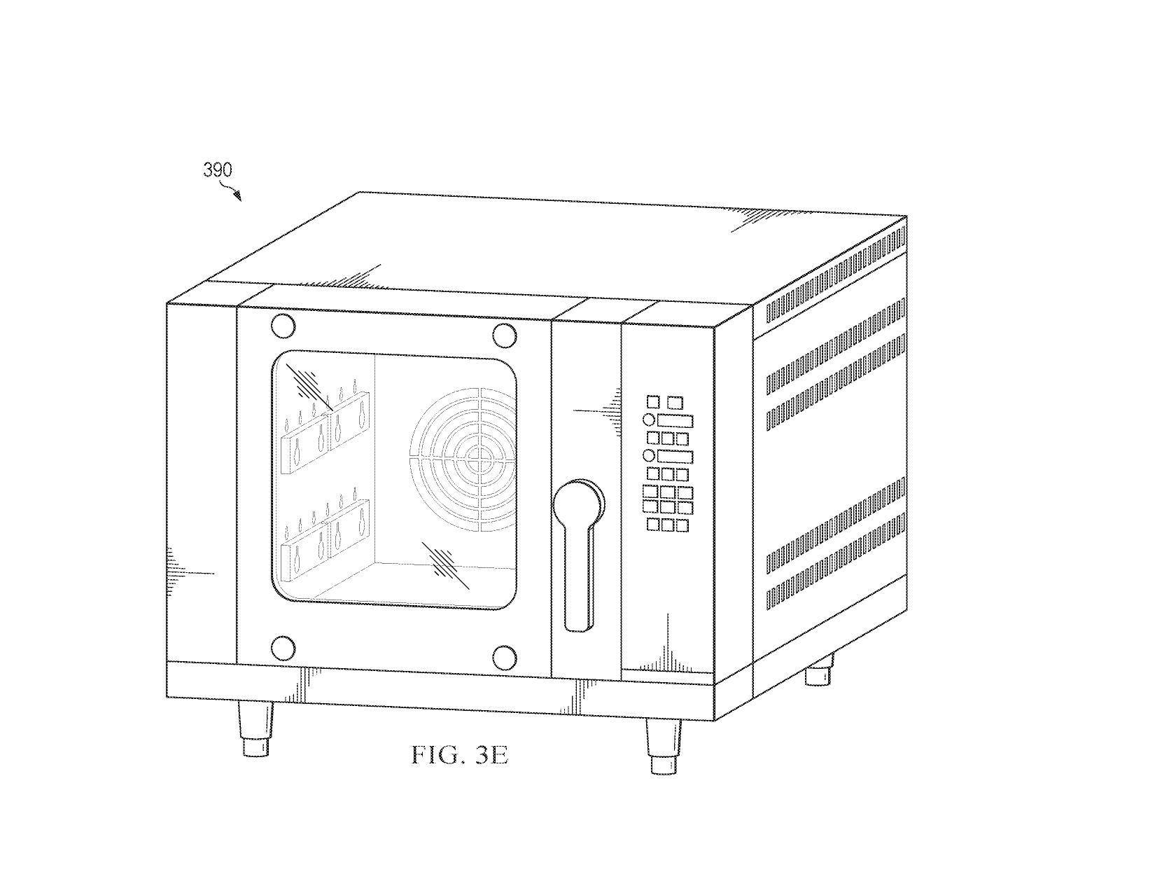

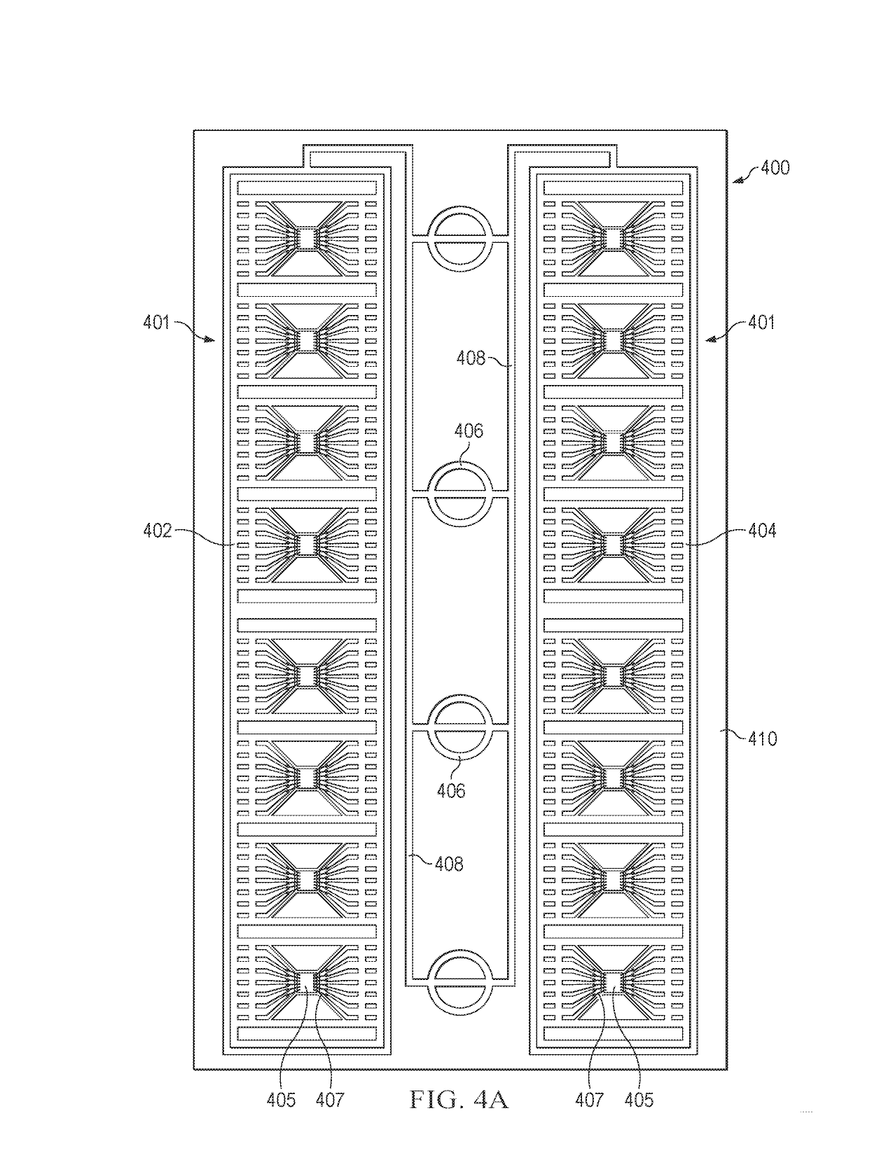

FIGS. 4A and 4B are a process flow depicting the manufacture of a semiconductor package including halogen-cured acid anhydride materials, in accordance with various examples. More specifically, FIGS. 4A and 4B depict the manufacture of a different kind of semiconductor package than the semiconductor package 350 described above. Like the semiconductor package 350, however, the semiconductor package manufactured by the process flow of FIGS. 4A and 4B includes a halogen-cured acid anhydride material. FIG. 4A is a top-down view of a portion of a mold chase 400. The mold chase 400 includes cavities 401 in which lead frame strips 402 and 404 are positioned. Semiconductor dies 405 and bond wires 407 may be coupled to the lead frame strips 402 and 404. The mold chase 400 may include mold pots 406 and runners 408 extending from the mold pots 406 to the cavities 401. Doors 410 may be opened and closed to uncover or cover the lead frame strips 402 and 404. In some examples, lids may be useful in lieu of doors 410. As shown in FIG. 4B, the doors 410 may be closed, and acid anhydride material may be injected into the mold pots 406. The acid anhydride material flows through the runners 408 and into the cavities 401, covering the lead frame strips 402 and 404 and the various structures (e.g., the semiconductor dies 405 and the bond wires 407) coupled to the lead frame strips 402 and 404. Step 102 of the method 100 may be performed in this way. A halogen heating lamp 412 may be suspended over the mold chase 400. The halogen heating lamp 412 may direct heat directly toward the mold chase 400 after the acid anhydride material has been dispensed into the mold pots 406 and has covered the various structures seated within the cavities 401. Applying heat from the halogen heating lamp 412 causes an outer portion of the acid anhydride material to rapidly cure, conferring similar moisture-blocking benefits as those described above. In this way, step 104 of the method 100 is performed. To facilitate even curing of the exterior of the acid anhydride material, the mold chase 400 may be heat conductive and thus may transfer heat from the halogen heating lamp 412 to most or all portions of the mold chase 400. In some examples, multiple halogen heating lamps 412 may be positioned around the mold chase 400 to facilitate even heating.

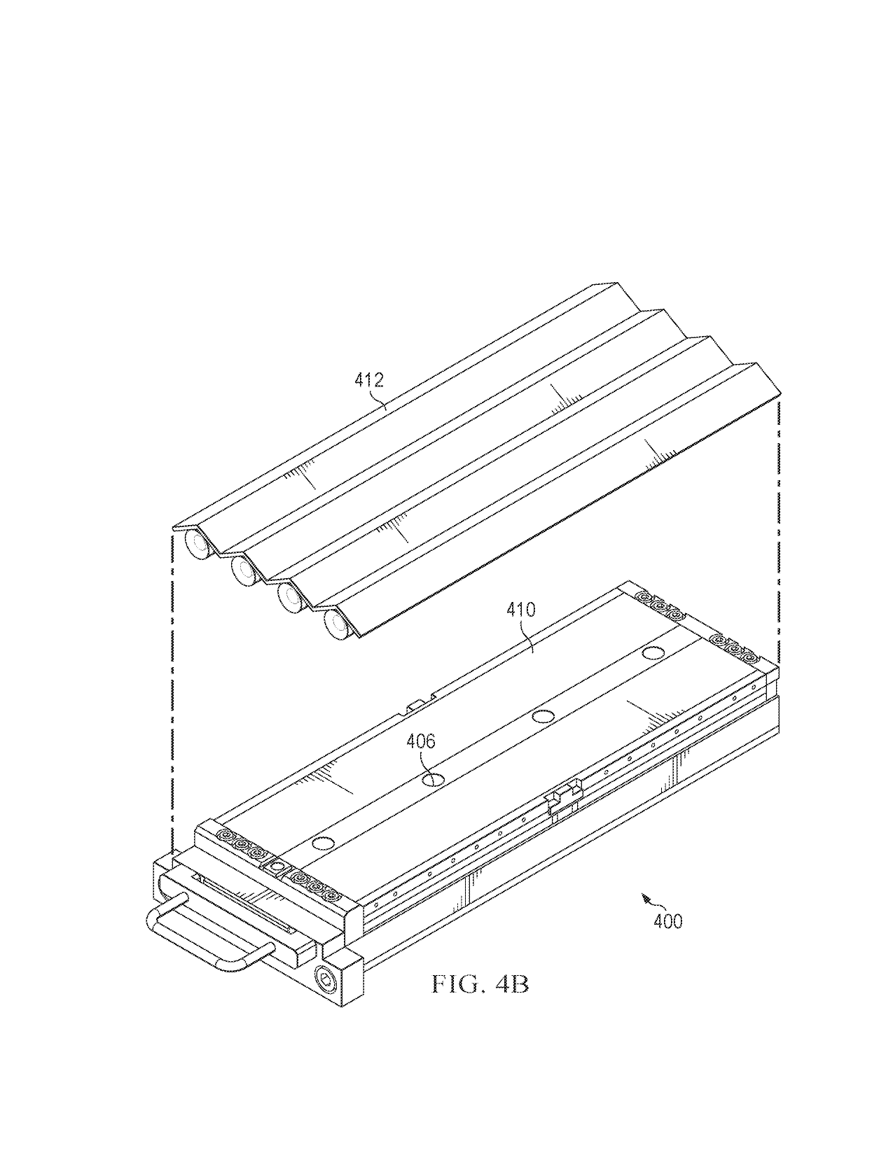

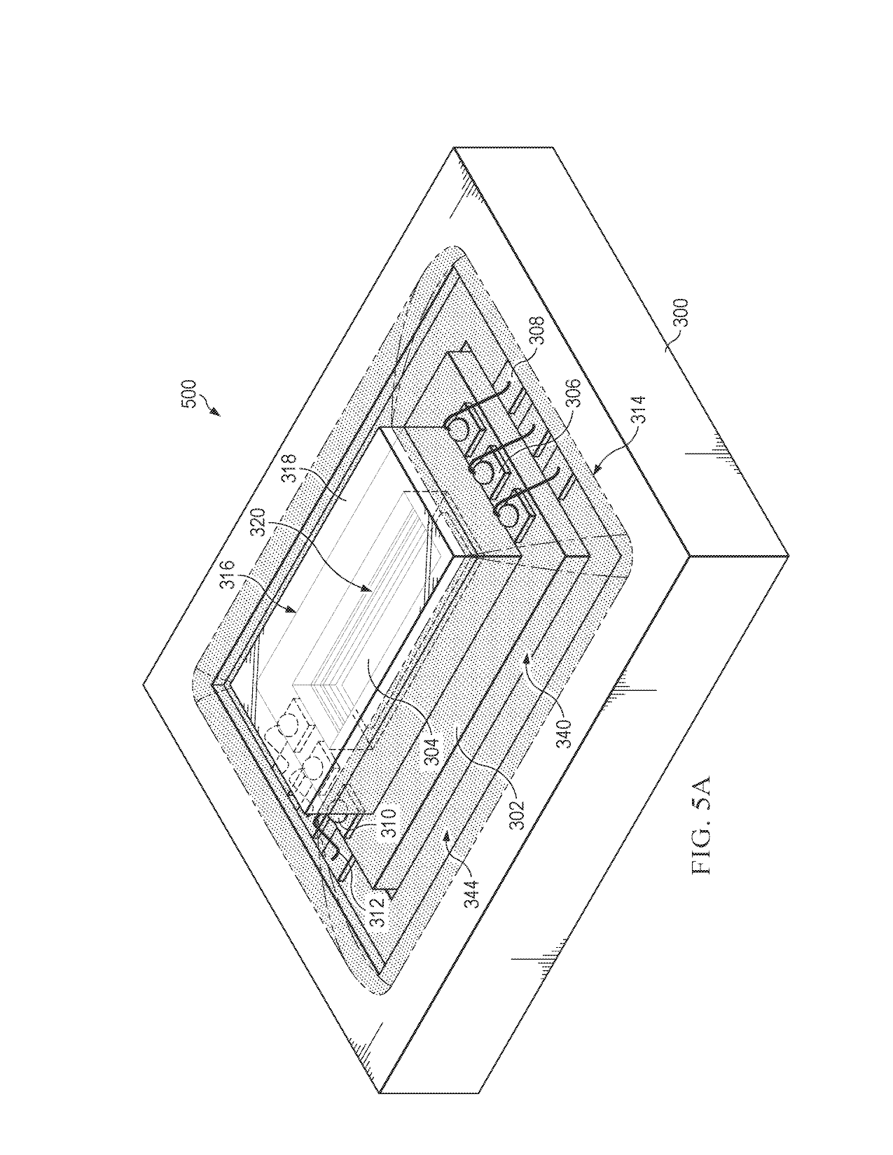

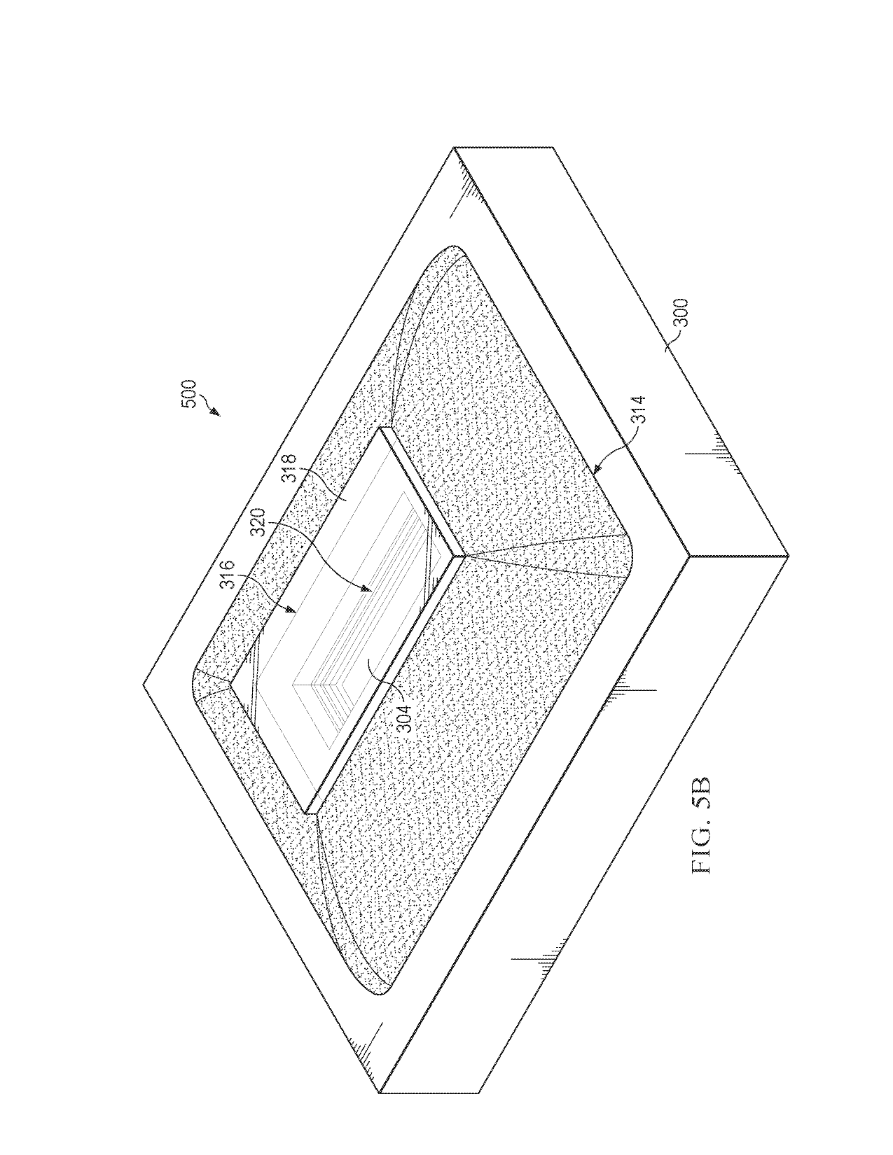

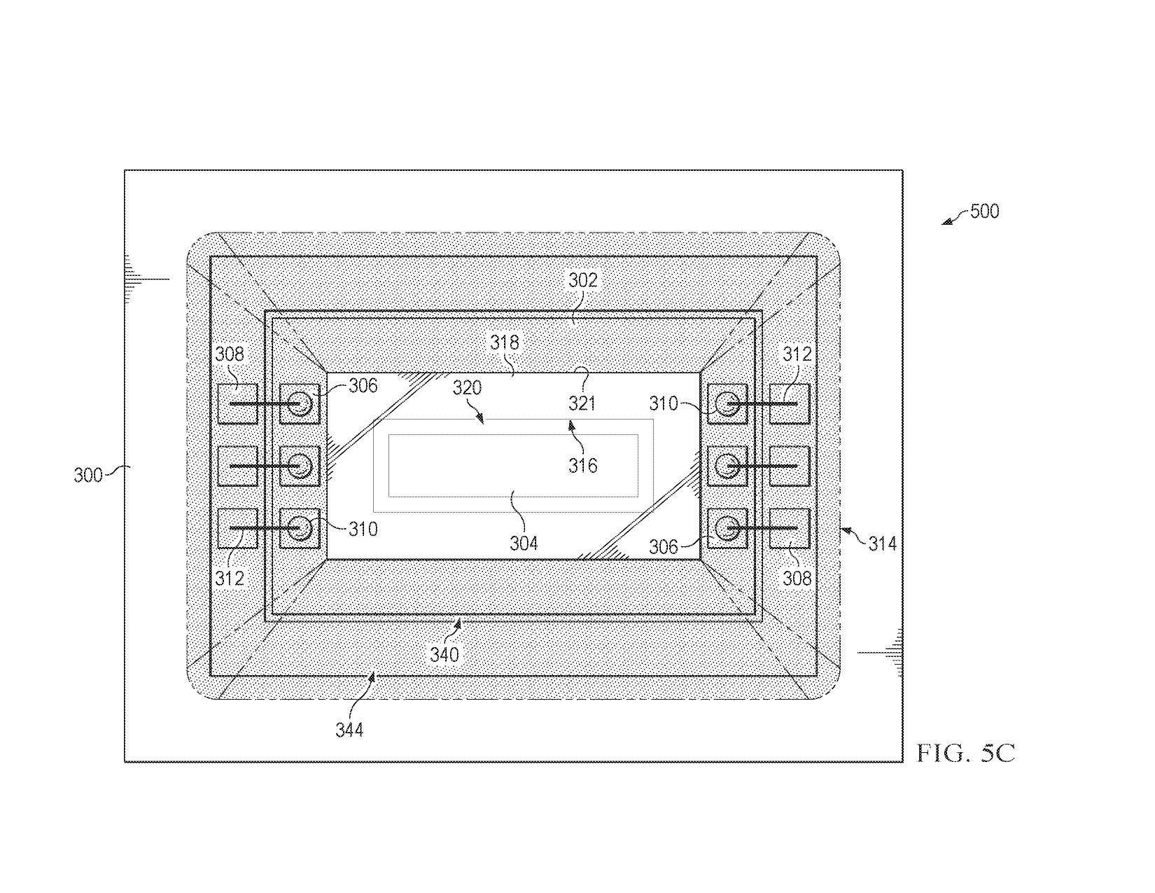

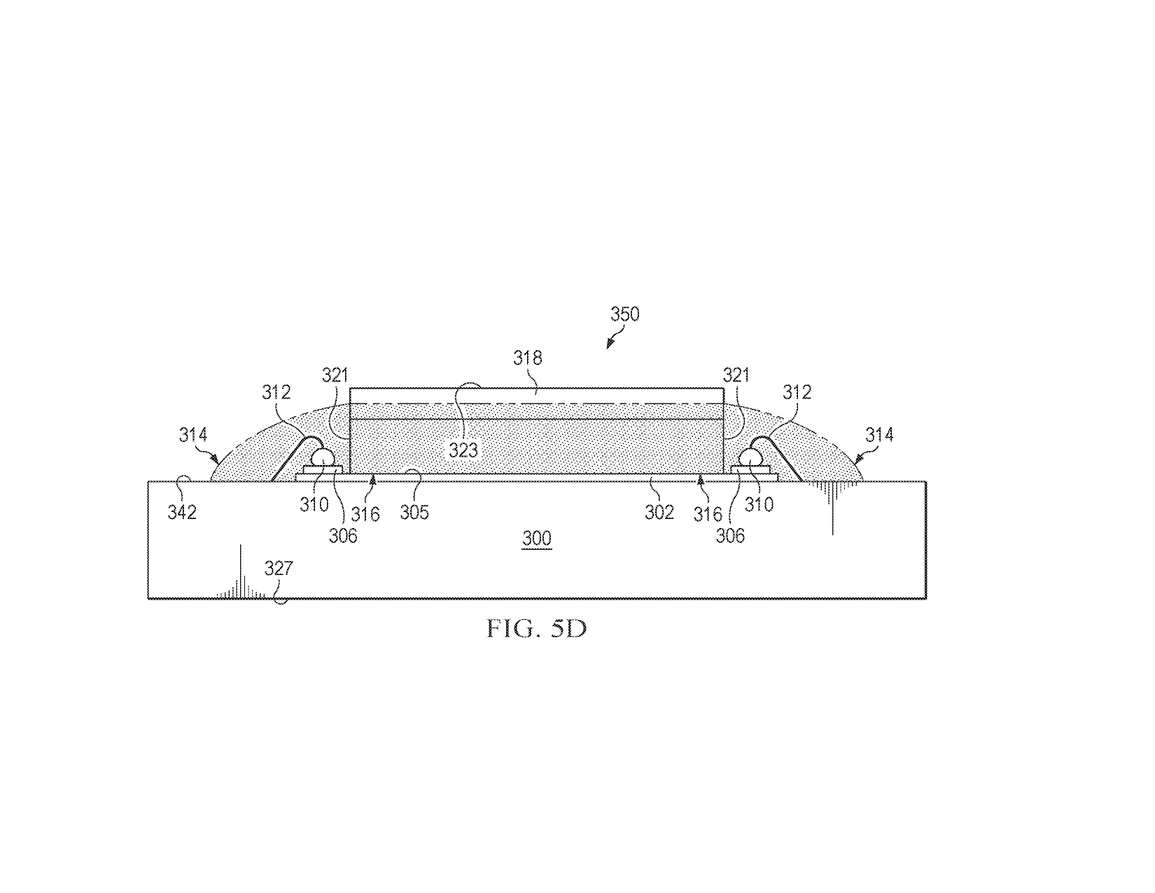

FIGS. 5A-5D are perspective, perspective, top-down, and profile views, respectively, of a semiconductor package including halogen-cured acid anhydride materials, in accordance with various examples. Specifically, FIGS. 5A-5D show a semiconductor package 500 manufactured according to the method 100 of FIG. 1 and the process flow of FIGS. 3A-3E. As shown, the semiconductor package 500 shown in FIGS. 5A-5D is identical to the semiconductor package 350 of FIG. 3D, except that the acid anhydride material 314 has been fully cured. Because the halogen heating lamp 260 (FIG. 2B) rapidly cured an outer portion of the acid anhydride material 314, moisture did not penetrate into the acid anhydride material 314, and thus after the acid anhydride material 314 has fully cured, the physicochemical properties of the acid anhydride material 314 are uniform throughout the acid anhydride material 314, as the dotted hashing extending uniformly throughout the acid anhydride material 314 indicates. Examples of such physicochemical properties may include the coefficient of thermal expansion (CTE) of the acid anhydride material 314, the glass transition temperature (Tg) of the acid anhydride material 314, the elastic modulus of the acid anhydride material 314, the dimensional stability of the acid anhydride material 314, and the flexural strength of the acid anhydride material 314. Moisture interacts with acid anhydride materials to modulate at least these physicochemical properties, and because the rapid curing provided by halogen heating as described herein prevents moisture penetration into the acid anhydride material 314, the physicochemical properties of the acid anhydride material 314 do not vary between an outermost portion of the acid anhydride material 314 to an innermost portion of the acid anhydride material 314. Rather, the physicochemical properties of the acid anhydride material 314 are consistent throughout a volume of the acid anhydride material 314, meaning that a physicochemical property measurement at any point A in the acid anhydride material 314 varies by less than 1% when compared to a reference measurement of that same physicochemical property at any point B in the acid anhydride material 314. For example, a particular instance of epoxy may have a consistent CTE throughout the volume of that instance of epoxy. Thus, if that instance of epoxy has a CTE of 10 parts per million per degree Celsius (ppm/deg C) at a random point A, then all other CTE measurements performed on that instance of epoxy must be less than 10.1 ppm/deg C and must be greater than 9.9 ppm/deg C.

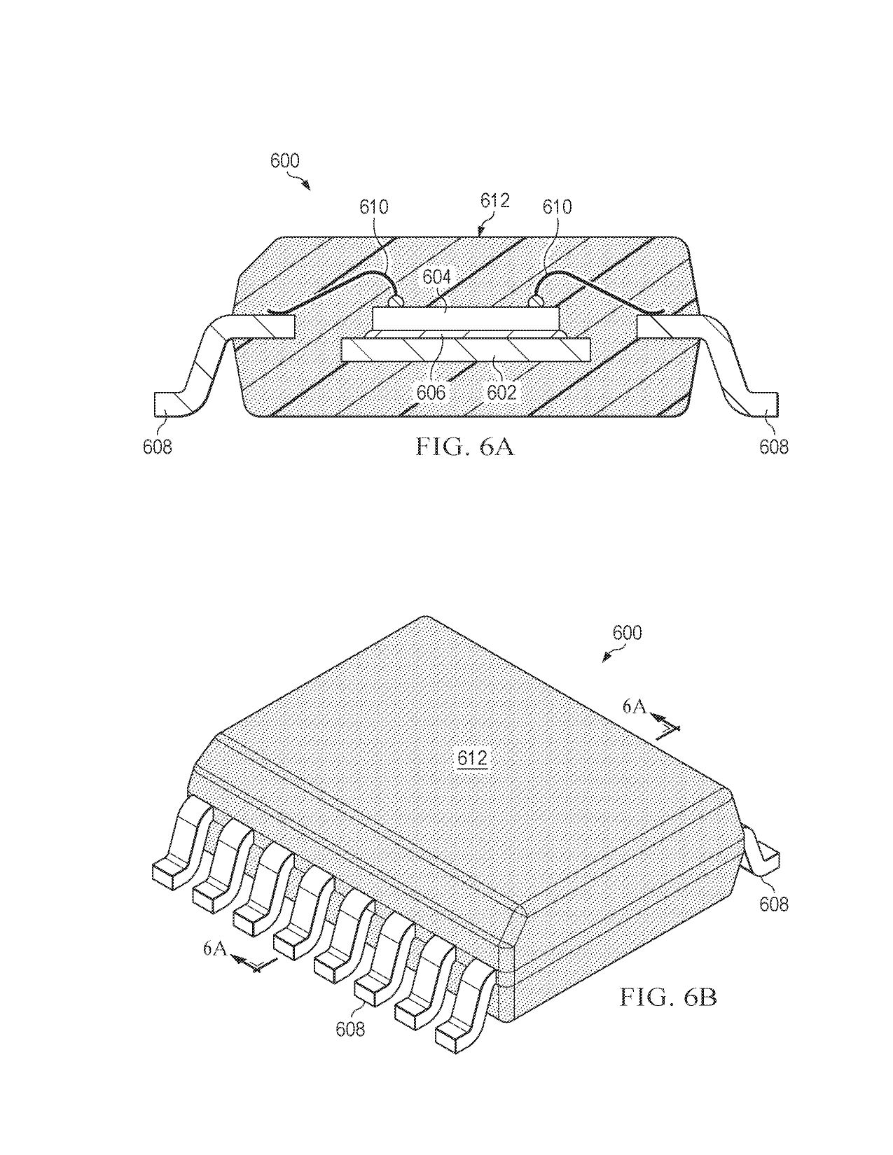

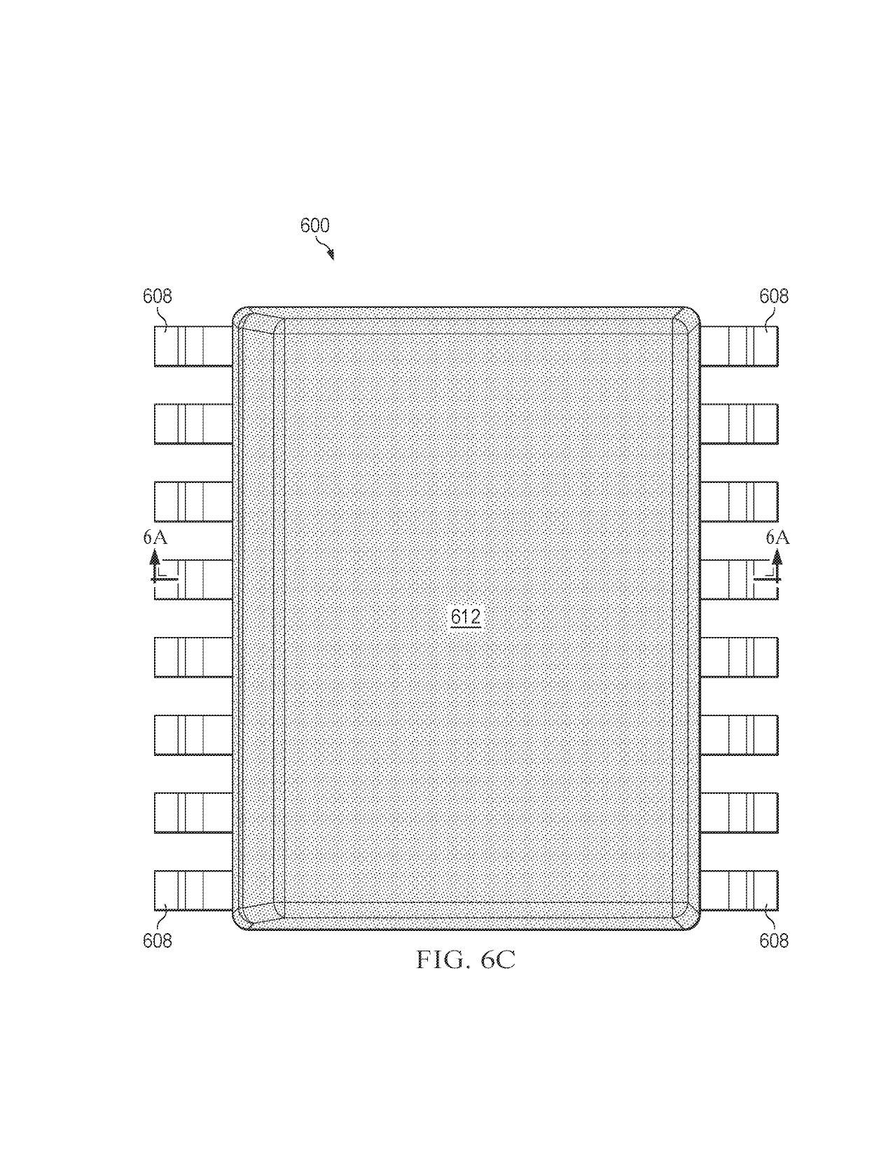

FIGS. 6A-6C are cross-sectional, perspective, and top-down views, respectively, of a semiconductor package including halogen-cured acid anhydride materials, in accordance with various examples. Specifically, FIGS. 6A-6C show a semiconductor package manufactured according to the method 100 of FIG. 1 and the process flow of FIGS. 4A and 4B. A semiconductor package 600 includes a die attach pad 602, a semiconductor die 604 coupled to the die attach pad 602 by die attach material 606, conductive terminals 608 (e.g., leads), and bond wires 610 coupled to the semiconductor die 604 and to the conductive terminals 608. An acid anhydride material 612 covers and contacts the various structures of the semiconductor package 600. The conductive terminals 608 are exposed to an exterior of the acid anhydride material 612. Because the acid anhydride material 612 is rapidly cured by the halogen heating lamp 412 (FIG. 4B) as described above, an outer portion of the acid anhydride material 612 hardens and prevents moisture entry into the acid anhydride material 612, resulting in consistent physicochemical properties throughout a volume of the acid anhydride material 612, as the dotted hashing indicates. Consequently, the negative consequences that result from inconsistent physicochemical properties are rendered moot.

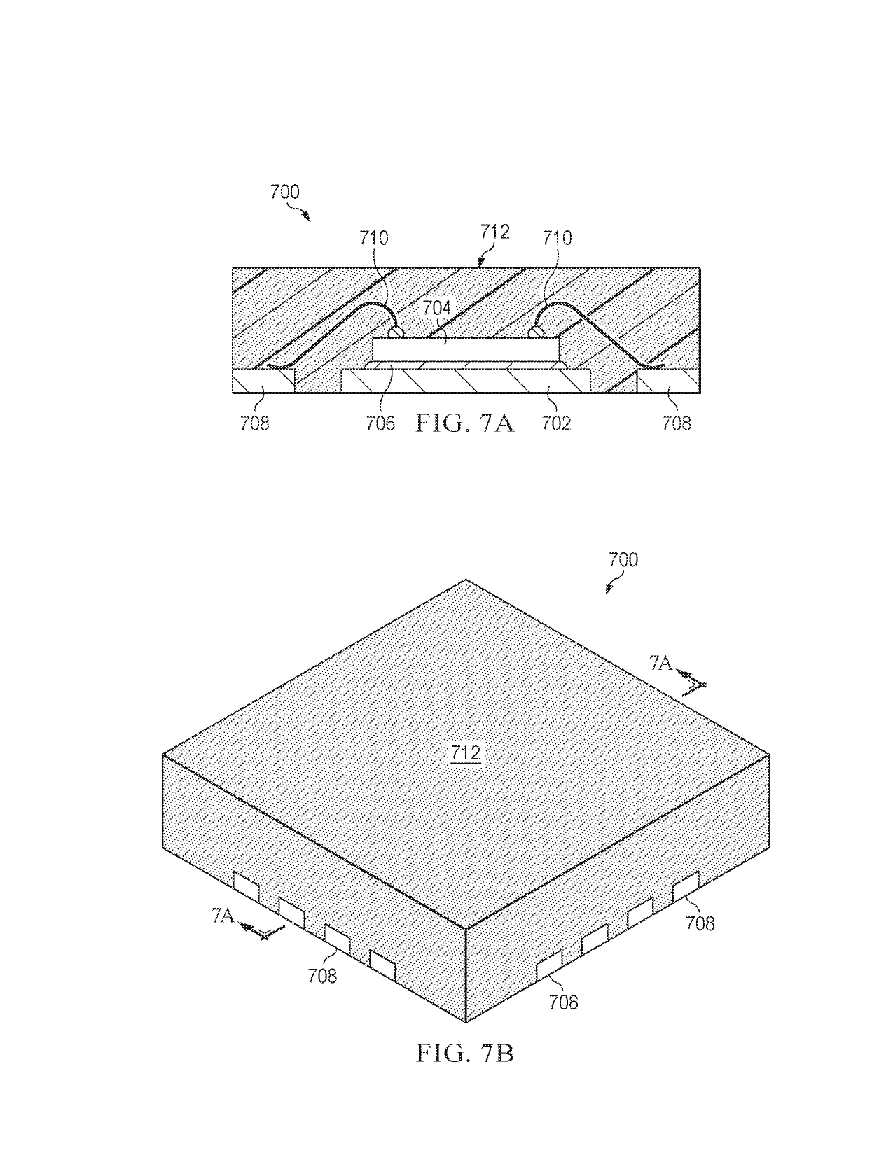

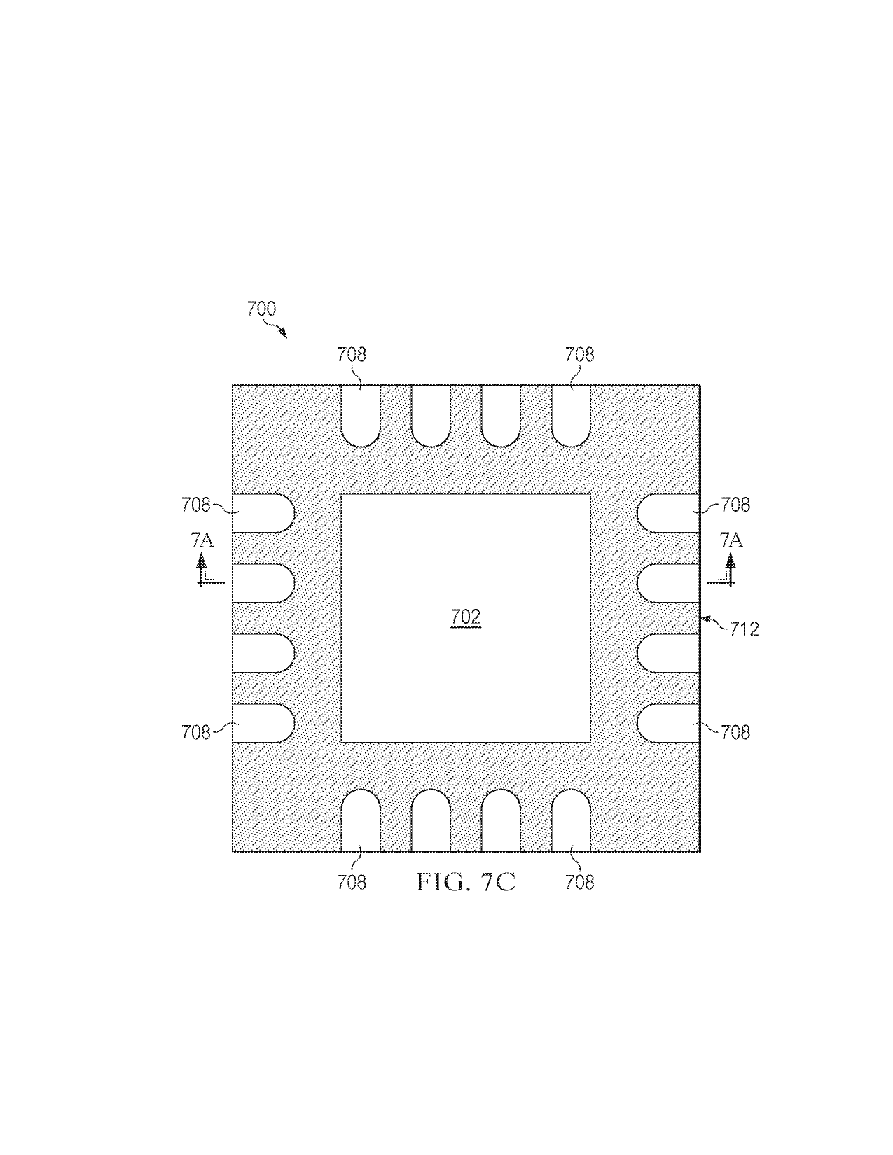

FIGS. 7A-7C are cross-sectional, perspective, and bottom-up views, respectively, of a semiconductor package including halogen-cured acid anhydride materials, in accordance with various examples. Specifically, FIGS. 7A-7C show a semiconductor package (e.g., a quad flat no lead (QFN) package) manufactured according to the method 100 of FIG. 1 and the process flow of FIGS. 4A and 4B. A semiconductor package 700 includes a die attach pad 702, a semiconductor die 704 coupled to the die attach pad 702 by die attach material 706, conductive terminals 708, and bond wires 710 coupled to the semiconductor die 704 and to the conductive terminals 708. An acid anhydride material 712 covers and contacts the various structures of the semiconductor package 700. The conductive terminals 708 are exposed to an exterior of the acid anhydride material 712. Because the acid anhydride material 712 is rapidly cured by the halogen heating lamp 412 (FIG. 4B) as described above, an outer portion of the acid anhydride material 712 hardens and prevents moisture entry into the acid anhydride material 712, resulting in consistent physicochemical properties throughout a volume of the acid anhydride material 712, as the dotted hashing indicates. Consequently, the negative consequences that result from inconsistent physicochemical properties are rendered moot.

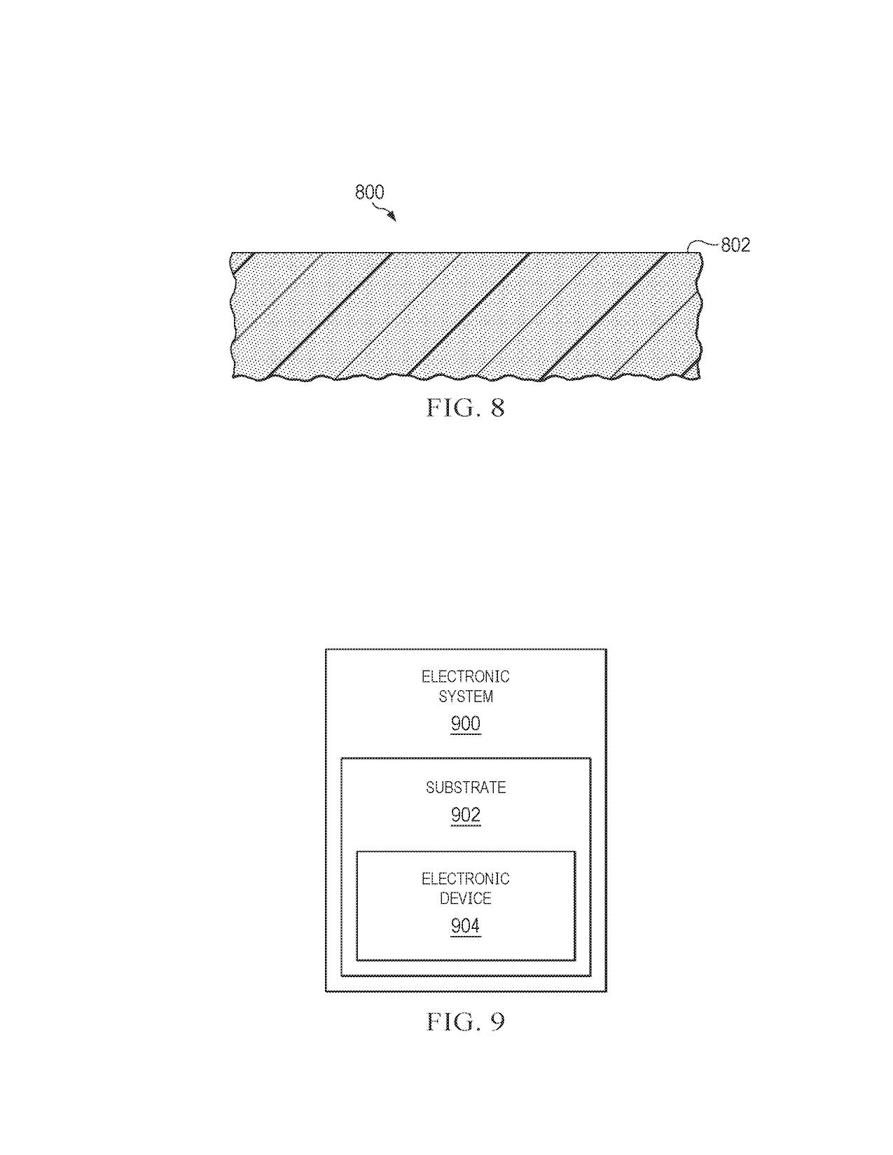

FIG. 8 is a cross-sectional view of a halogen-cured acid anhydride material 800, in accordance with various examples. The acid anhydride material 800 is an example of the acid anhydride materials 314, 612, and 712 after having been fully cured, first by halogen heating and subsequently by another heat source or at room temperature over an extended period of time. Numeral 802 represents an outermost surface of the acid anhydride material 800, as thus FIG. 8 depicts a cross-sectional slice extending through a thickness of the acid anhydride material 800. As the uniform dotting throughout the acid anhydride material 800 indicates, the physicochemical properties of the acid anhydride material 800 are consistent across the cross-section of the acid anhydride material 800, meaning that a physicochemical property measurement at any point A in the acid anhydride material 800 varies by less than 1% when compared to a reference measurement of that same physicochemical property at any point B in the acid anhydride material 800. Furthermore, and as explained above, the physicochemical properties of the acid anhydride material 800 are consistent throughout a volume of the acid anhydride material 800.

FIG. 9 is a block diagram of an electronic system including a semiconductor package having a halogen-cured acid anhydride material, in accordance with various examples. More specifically, FIG. 9 shows an electronic system 900 including a substrate 902 (e.g., a printed circuit board (PCB)) and an electronic device 904 coupled to the substrate 902. Examples of the electronic system 900 include a smartphone, a tablet, a laptop computer, a desktop computer, a television, a wireless audio device (e.g., headphones), a video game console, a wireless Internet device, a drone, a sensor, an aircraft, a space craft, a road vehicle, a home appliance, etc. Examples of the electronic device 904 include the various semiconductor packages described herein, such as the semiconductor packages 350, 600, and 700. In some examples, the electronic device 904 is a MEMS device, such as accelerometers, gyroscopes, pressure sensors, humidity sensors, and microphones.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/- 1 percent of that parameter. Modifications are possible in the described examples, and other examples are possible within the scope of the claims.

As used herein, the terms “conductive terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. An electronic device, comprising:
a semiconductor die;
a bond pad coupled to the semiconductor die;
a bond wire coupled to the bond pad; and
an acid anhydride material covering the bond wire and having a physicochemical property that varies by less than 1% throughout a volume of the acid anhydride material relative to a reference measurement of the physicochemical property in the acid anhydride material.

2. The electronic device of claim 1, wherein the physicochemical property is selected from the group consisting of: coefficient of thermal expansion, glass transition temperature (Tg), elastic modulus, dimensional stability, and flexural strength.

3. The electronic device of claim 1, wherein the electronic device is a semiconductor package, the acid anhydride material covers the semiconductor die and the bond pad, and the semiconductor package comprises a conductive terminal coupled to the bond wire and accessible from outside of the acid anhydride material.

4. The electronic device of claim 1, wherein the electronic device is a microelectromechanical systems (MEMS) device.

5. The electronic device of claim 4, wherein the electronic device includes a micromirror array.

6. An electronic device, comprising:
a semiconductor die including circuitry;
a microelectromechanical systems (MEMS) device over the semiconductor die and coupled to the circuitry;
a bond pad over the semiconductor die and coupled to the circuitry;
a bondline on the semiconductor die between the MEMS device and the bond pad, the bondline circumscribing the MEMS device ;
a cap over the bondline and over the MEMS device ;
a bond wire coupled to the bond pad; and
an acid anhydride material covering the bond wire and having a physicochemical property that is consistent throughout a volume of the acid anhydride material.

7. The electronic device of claim 6, wherein the physicochemical property is selected from the group consisting of: coefficient of thermal expansion, glass transition temperature (Tg), elastic modulus, dimensional stability, and flexural strength.

8. The electronic device of claim 6, wherein the MEMS device includes a micromirror and the cap is transparent.

9. The electronic device of claim 6, wherein the acid anhydride material is selected from the group consisting of a mold compound and a glob-top.

10. A method for manufacturing an electronic device, comprising:
dispensing an acid anhydride material on a bond wire, the bond wire coupled to a semiconductor die via a bond pad;
applying heat to the acid anhydride material by a halogen heating lamp; and
curing the acid anhydride material after the application of the heat.

11. The method of claim 10, further comprising applying the heat by the halogen heating lamp within 3 minutes of the dispensing of the acid anhydride material on the bond wire.

12. The method of claim 10, wherein applying the heat to the acid anhydride material is performed by the halogen heating lamp for a period of time between 1 minute and 10 minutes, at a temperature ranging from 100 degrees Celsius to 150 degrees Celsius.

13. The method of claim 10, wherein the dispensing comprises injecting the acid anhydride material into a mold chase containing the semiconductor die, the bond pad, and the bond wire.

14. The method of claim 13, wherein applying the heat includes heating the mold chase with the halogen heating lamp.

15. The method of claim 10, wherein, when dispensing the acid anhydride material on the bond wire, the semiconductor die, the bond pad, and the bond wire are on a conveyor belt.

16. The method of claim 15, further comprising using a dispense station to dispense the acid anhydride material on the bond wire and using the dispense station to apply the heat, the dispense station including the halogen heating lamp.

17. The method of claim 10, wherein a physicochemical property of the acid anhydride material is consistent throughout a volume of the acid anhydride material, the physicochemical property selected from the group consisting of: coefficient of thermal expansion, glass transition temperature (Tg), elastic modulus, dimensional stability, and flexural strength.

18. The method of claim 10, wherein the bond wire is coupled to a conductive terminal that is exposed to an exterior of the acid anhydride material.

19. The method of claim 10, wherein the semiconductor die is included in a microelectromechanical systems (MEMS) device.

20. The method of claim 10, wherein curing the acid anhydride material after the application of the heat includes causing a physicochemical property of the acid anhydride material to be consistent throughout a volume of the acid anhydride material.
